(19) United States
(12) Patent Application Publication
(10) Pub. No.: US 2006/0060845 A1
(43) Pub. Date: Mar. 23, 2006

(54) Bond pad redistribution layer for thru semiconductor vias and probe touchdown

(76) Inventors: Narahari Ramanuja, Fremont, CA (US); Florence R. Pon, Folsom, CA (US); Timothy M. Takeuchi, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/946,262

(22) Filed: Sep. 20, 2004

(51) Int. Cl. H01L 29/10

(52) U.S. Cl. 257/48

(57) ABSTRACT

A semiconductor device having a conductive layer above a dielectric layer and a top metal layer. The conductive layer is patterned to form an alternate probe area to test the functionality of active circuitry within the semiconductor device and patterned to electrically route a thru semiconductor via within the semiconductor device to an alternate junction point.

### BACKGROUND OF THE INVENTION

1. Field of the Invention

The present invention relates to the field of integrated circuits and more specifically, to a bond pad redistribution layer for relocating thru semiconductor vias and for preventing corrosion of metal layers because of probe touchdowns.

2. Discussion of Related Art

In the manufacture of microelectronic devices, packaging density is becoming increasingly important. Stacking of dice is one way to improve the packaging density of microelectronic devices. Stacked microelectronic devices are typically formed by etching thru semiconductor vias (TSVs) through individual integrated circuits on a wafer, dicing the wafers into individual die, and then stacking the die by vertically aligning the TSVs of each die being stacked to form an electrical contact.

Furthermore, to improve density, copper has replaced the use of aluminum in metal layers of many integrated circuits because copper tends to require thinner metal layers because of the improved conductivity of copper as compared to aluminum (e.g., copper is less resistive than aluminum and therefore requires less surface area than aluminum when used for the same application). In addition, testing requirements for semiconductor devices has dramatically increased because greater package density requires testing of more transistors within the same physical area in order to insure reliability.

FIG. 1A illustrates a side view of a first die 102 and a second die 104, each having vertically aligned thru semiconductor vias 109 that are in electrical contact with each other to form a stacked device 150. A package substrate 100 is below the first die 102 and the second die 104. The use of vertically aligned thru semiconductor vias 109 is typically used to form an electrical connection between the first die 102 and the second die 104. As such, the thru semiconductor vias 109 electrically connect the first die 102 and the second die 104 together. The use of thru semiconductor vias 109 requires that each thru semiconductor via 109 on the first die 102 and each thru semiconductor via 109 on the second die 104 be vertically aligned so that an electrical connection is formed between the first die 102 and the second die 104. If there is an offset in the alignment of the thru semiconductor vias 109, there is no electrical connection between the first die 102 and the second die 104. (e.g., there are multiple thru semiconductor vias 109 on each die that must be aligned as illustrated on the first die 102 in FIG. 1B).

In FIG. 1A, the first die 102 includes an active region 103, and the second die 104 includes an active region 105 (e.g., an active region includes the metal layers of a particular die on which there is active transistor circuitry). Keep-out zones 110 exist in both the first die 102 and the second die 104. The keep-out zones 110 are areas within each one of the first die 102 and the second die 104 in which no transistors can reside (e.g., therefore the keep-out zones are inactive regions on each die). The keep-out zones 110 are unavoidable because the thru semiconductor vias 109 are typically formed by a metal that may diffuse into the active region 103 and 105 and cause charge loss and contamination within the active circuit areas (transistors) when the thru semiconductor vias 109 are etched through the first die 102 and through the second die 104 (e.g., reactive ions during etch process).

FIG. 1B illustrates a top view of the first die 102 having a set of thru semiconductor vias 109 and a set of bond pads 122. Each bond pad 122 includes a probe point 124 on which a probe (e.g., a probe 140 as shown in FIG. 1C) is placed to electrically test the circuitry within first die 102. While the probe point 124 is illustrated in the center of each bond pad 122 in FIG. 1B, the probe point 124 is typically located anywhere on the bond pad 122.

FIG. 1C illustrates a cross sectional view around a bond pad 122 (e.g., a bond pad 122 on a first die 102 as shown in FIG. 1B) and the corrosion of a top metal layer 146 from touchdowns of the probe 140 onto the bond pad 122 (e.g., the bond pad 122 may be the exposed portion of the top metal layer 146 or may include an aluminum cap 115 directly above the top metal layer 146). A probe 140 typically is placed onto the bond pad 122 (e.g., during a SORT process) to test the functionality of a die on which the bond pad 122 resides. The probe point 124 is the point where the probe 140 comes into contact with the bond pad 122. The probe 140 is often repeatedly placed on to the same probe point 124 in order to perform a thorough check of the functionality of a particular die. The repeated placements of the probe 140 onto the bond pad 122 results in the exposure of the top metal layer 146 to air. Unfortunately, the top metal layer 146 is typically copper which oxidizes when exposed to air and therefore corrodes around the probe point 124. This corrosion typically results in a loss of functionality and reliability of an integrated circuit.

### BRIEF DESCRIPTION OF THE DRAWINGS

The present invention is illustrated by way of example and not limitation in the figures of the accompanying drawings in which like references indicate similar elements.

FIG. 1A illustrates a side view of a first die and a second die, each having vertically aligned thru semiconductor vias that are in electrical contact with each other to form a stacked device.

FIG. 1B illustrates a top view of a first die having a set of thru semiconductor vias and a set of bond pads.

FIG. 1C illustrates a cross sectional view around a bond pad on a first die and the corrosion of a top metal layer from probe touchdowns onto the bond pad.

FIG. 2A illustrates a side view of a first die and a second die, each having edge positioned thru semiconductor vias that are in electrical contact with each other to form a stacked device using a redistribution layer, in accordance with an embodiment of the present invention.

FIG. 2B illustrates a top view of a first die having a set of edge positioned thru semiconductor vias, a set of bond pads, and a redistribution layer, in accordance with an embodiment of the present invention.

FIG. 2C illustrates a cross sectional view around a bond pad on a first die and probe touchdown onto a redistribution layer above a dielectric layer, in accordance with an embodiment of the present invention.

FIGS. 3A-3F illustrates a method for forming a redistribution layer on a first die, in accordance with an embodiment of the present invention.

FIG. 4 illustrates a top view of an exemplary die having a patterned redistribution layer that allows the exemplary die to be stacked with a second die that can be one of two sizes, and allows a larger alternate probe area for a probe touchdown, in accordance with an embodiment of the present invention.

FIG. 5 illustrates a side view of a first die and a second die, each having edge positioned thru semiconductor vias that are in electrical contact with each other to form a stacked device through the use of a redistribution layer and by vertical stacking, in accordance with an embodiment of the present invention.

### DETAILED DESCRIPTION OF THE PRESENT INVENTION

Embodiments of the present invention are integrated circuit devices having a redistribution layer and methods of formation of integrated circuits having a redistribution layer. In the following description numerous specific details have been set forth in order to provide a thorough understanding of the present invention. In other instances, well-known semiconductor fabrication processes and techniques have not been set forth in particular detail in order to avoid unnecessarily obscuring the present invention.

Embodiments of the present invention include a method of forming a redistribution layer to electrically connect edge positioned thru semiconductor vias of stacked dice and to decrease the size of each die within the stack by increasing the active circuit area within each die by preventing keep out zones. Embodiments of the invention include applying a probe to an alternate probe area on the redistribution layer rather than directly onto a bond pad above a top metal layer so as to prevent corrosion of the top metal layer. Embodiments of the present invention include using the redistribution layer solely for alternate probe touchdown areas and/or solely for electrically connecting edge positioned thru semiconductor vias of stacked dice. Embodiments of the present invention including using the redistribution layer both for alternate probe touchdown areas and for electrically connecting edge positioned thru semiconductor vias of stacked dice. Embodiments of the invention include patterning a conductive layer (redistribution layer) that extends from a bond pad to an alternate probe area on a semiconductor device and placing a probe on the alternate probe area so as to test the functionality of the active circuitry within the semiconductor device.

An advantage of the present invention includes increasing reliability of integrated circuits by preventing corrosion of the metal layers within a semiconductor device. Another advantage of the present invention includes decreasing the physical size of stacked devices by increasing the useable active circuit area by edge positioning thru semiconductor vias within each die of a stacked device and by using a redistribution layer to connect the thru semiconductor vias together.

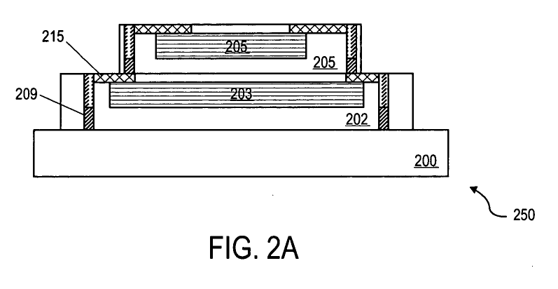

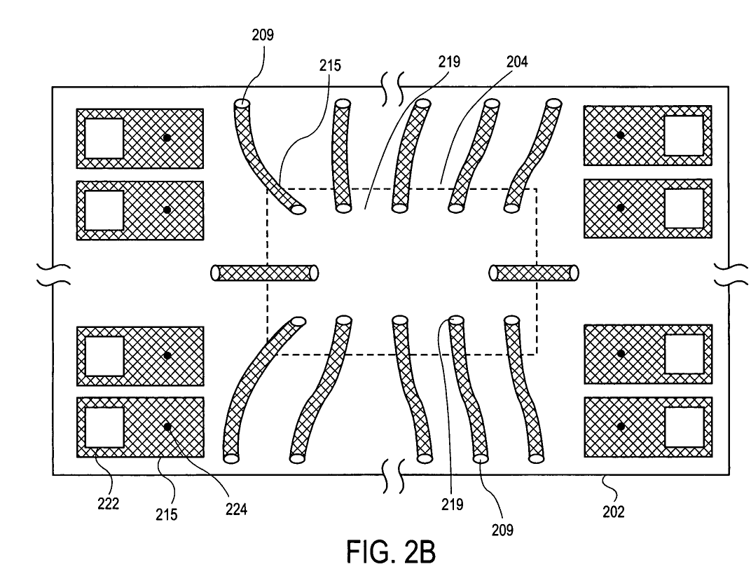

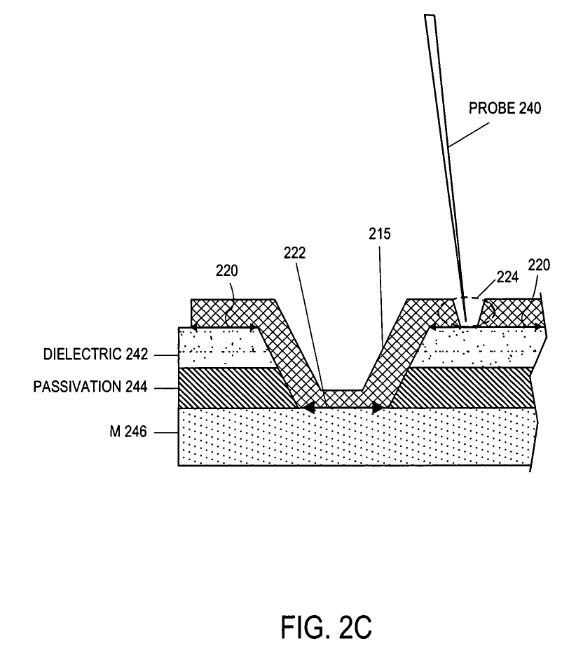

FIG. 2A illustrates a side view of a first die 202 and a second die 204, each having edge positioned (e.g., positioned away from the active circuit areas on each die) thru semiconductor vias 209 that are in electrical contact with each other to form a stacked device 250 using a redistribution layer 215, in accordance with an embodiment of the present invention. A package substrate 200 is below the first die 202 and the second die 204. In one embodiment of the present invention, the redistribution layer 215 electrically connects the thru semiconductor vias 209 within the first die 202 with the thru semiconductor vias 209 within the second die 204 (e.g., there may be multiple thru semiconductor vias 209 within each die as shown the top view of the die 202 in FIG. 2B).

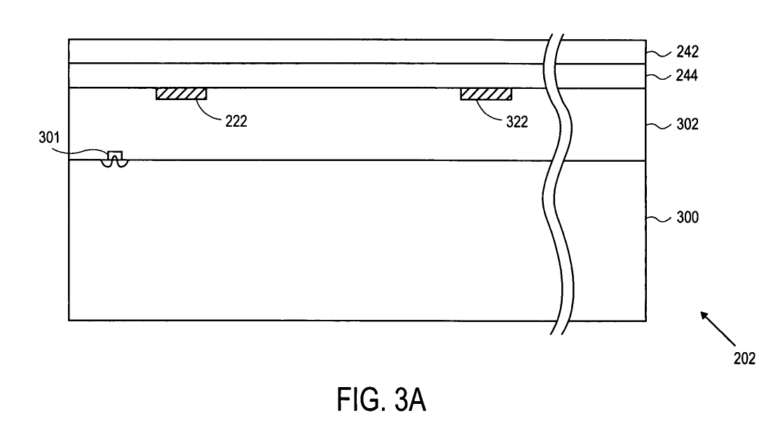

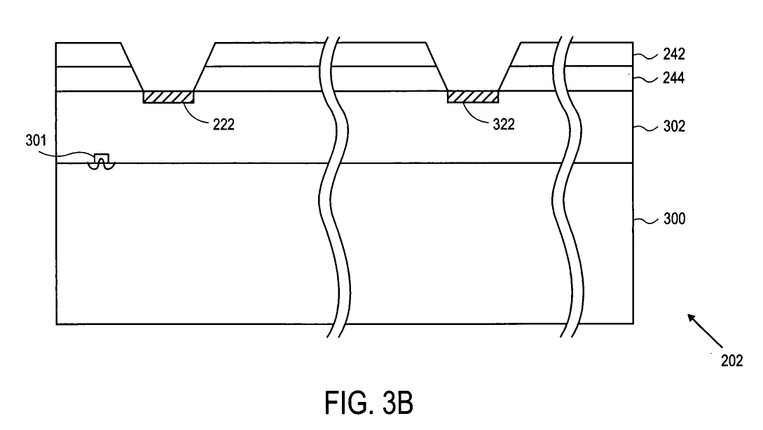

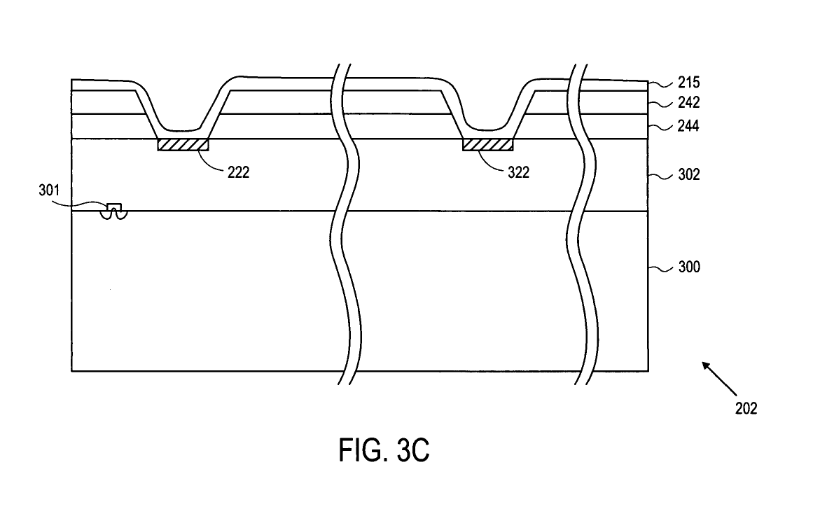

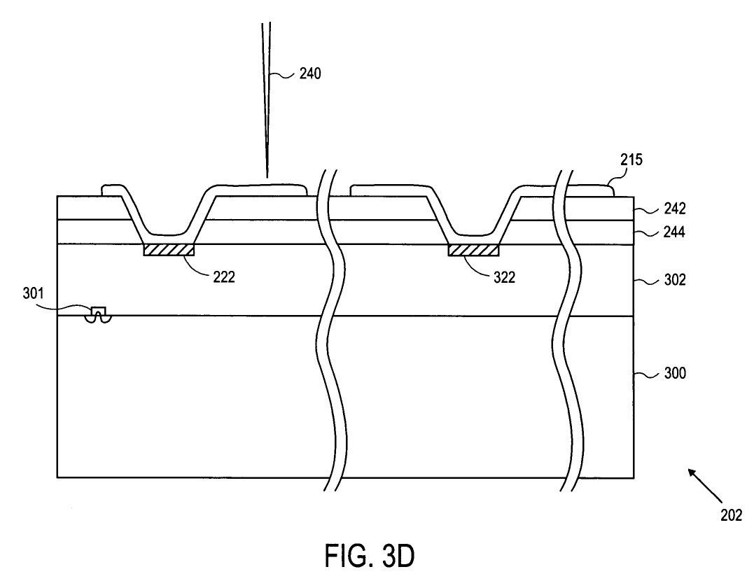

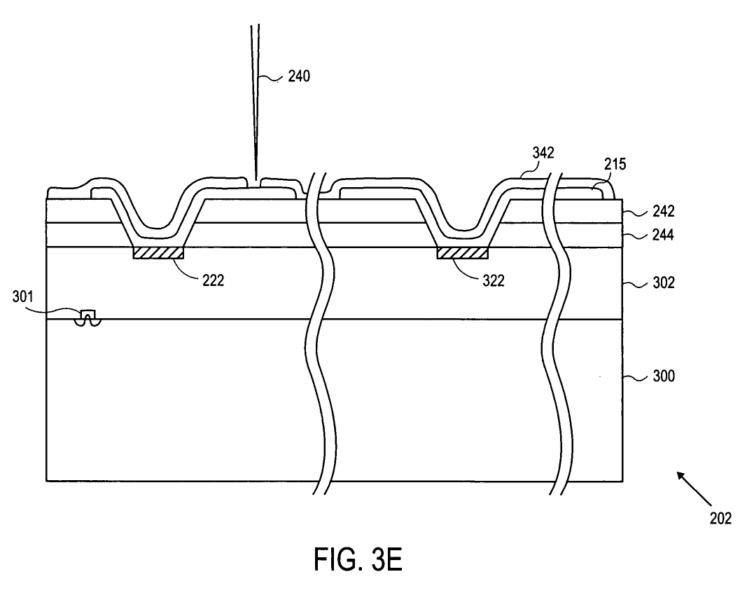

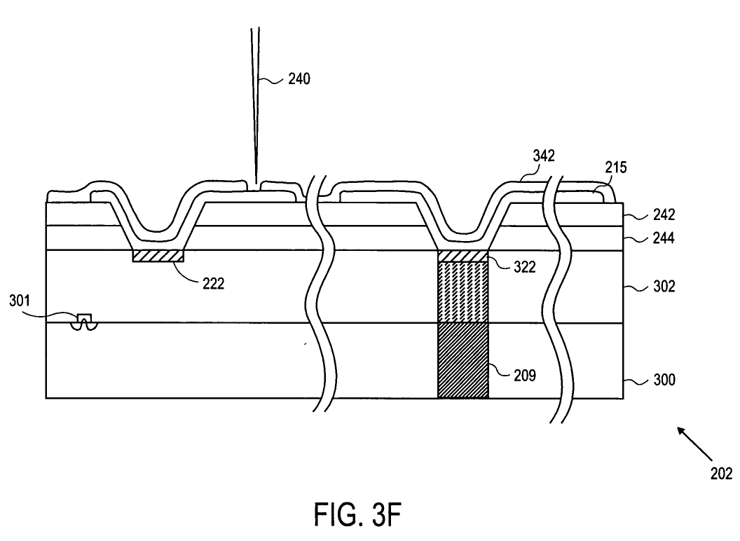

In one embodiment of the present invention, the redistribution layer 215 is 0.05% copper doped aluminum. In one embodiment of the present invention, the redistribution layer 215 is greater than 1 micron in thickness when a 0.05% copper doped aluminum is used. In one embodiment of the present invention, the redistribution layer 215 includes a titanium base that is thicker than 1000 angstroms. In one embodiment of the present invention, the redistribution layer 215 is approximately 2-6 microns in thickness when the redistribution layer 215 is pure aluminum. In one embodiment of the present invention, the redistribution layer 215 is fabricated above a dielectric layer 242 (as shown in FIG. 2C) that may be silicon-oxide, silicon-nitride, silicon carbide, polymer, spin on glass, and/or resins. In one embodiment of the present invention, the redistribution layer 215 is fabricated before the first die 202 and/or the second die 204 have been cut from a wafer. In one embodiment of the present invention, an additional dielectric layer (e.g., such as dielectric layer 342 as shown in FIG. 3E) is formed above redistribution layer 215 in order to provide scratch protection to the redistribution layer 215.

In FIG. 2A, the stacked device 250 includes the first die 202 and the second die 204. Both the first die 202 and the second die 204 include a set of thru semiconductor vias 209. In one embodiment of the present invention, the thru semiconductor vias 209 are thru silicon vias. In one embodiment of the present invention, the thru semiconductor vias 209 are vias through any type of semiconductor material. (e.g., Silicon, Gallium Arsenide, Aluminum Nitride, etc.). In one embodiment of the present invention, there are multiple thru semiconductor vias 209 on each die as shown on the die 202 in FIG. 2B. The redistribution layer 215 on the second die 204 is not used (e.g., because it is the top most die of the stacked device 250) to relocate thru semiconductor vias 209 because there is no die stacked above the second die 204 (e.g., the second die 204 may be manufactured with a redistribution layer 215 as shown in FIG. 2C solely for probe 240 touchdown onto the redistribution layer 215 above a dielectric layer 242).

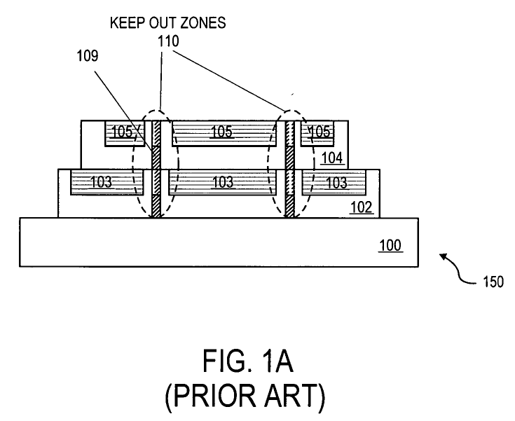

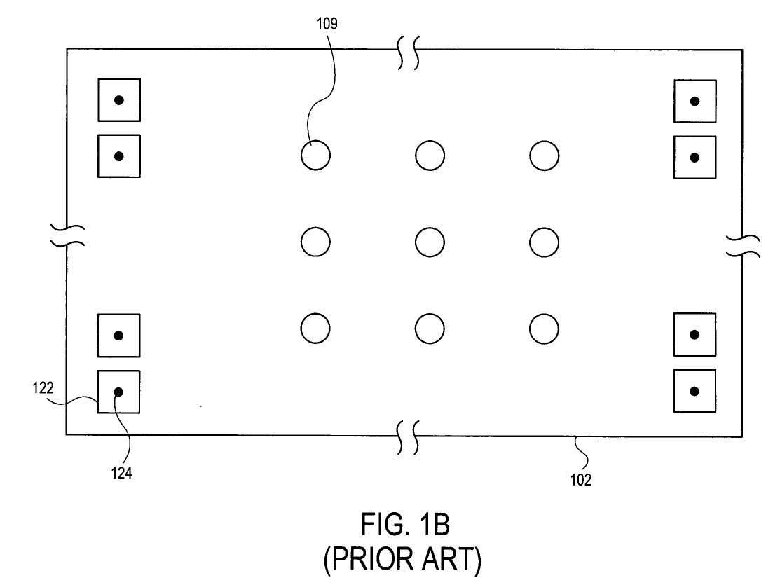

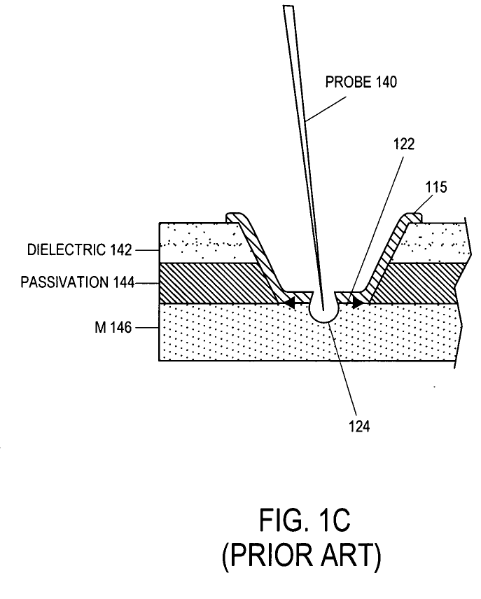

In FIG. 2A, the first die 202 includes an active region 203 and the second die 204 includes an active region 205 (e.g., the active regions may be areas of each die in which there is active transistor circuitry). The active region 203 in first die 202 and the active region 205 in the second die 204 have no keep-out zones because the thru semiconductor vias 209 are located at the edge of the first die 202 and at the edge of the second die 204 (e.g., away from the active circuit area of each die). Furthermore, the first die 202 and the second die 204 are electrically connected without requiring direct vertical alignment of their thru semiconductor vias 209 because of the use of the redistribution layer 215. As such, larger areas of the first die 202 and the second die 204 can be utilized for transistors and active circuitry (e.g., a keep-out zones 110 as shown in FIG. 1A are unnecessary in the stacked device 250 shown in FIG. 2A because the thru semiconductor vias 209 are routed around the edge of each die in FIG. 2A rather than through the center of each die as in FIG. 1A).

FIG. 2B illustrates a top view of a first die 202 having a set of edge positioned thru semiconductor vias 209, a set of die bond pads 222, and a redistribution layer 215, in accordance with an embodiment of the present invention. The redistribution layer 215 in FIG. 2B includes a probe point 224 on which a probe (e.g., a probe 240 as shown in FIG. 2C) is placed to electrically test the circuitry within the first die 202. While the probe point 224 is illustrated at a location a slight distance right of center of redistribution layer 215, the probe point 224 is typically located anywhere on the redistribution layer 215. In one embodiment of the present invention, the redistribution layer 215, next to the bond pad 222 in FIG. 2B is at least large enough to allow a probe (e.g., a probe 240 as shown in FIG. 2C) to be placed on it. In one embodiment, the redistribution layer 215 next to the bond pad 222 in FIG. 2B is at least as large as bond pad 222.

In FIG. 2B, the redistribution layer 215 also routes each of the thru semiconductor vias 209 on the first die 202 to junction points 219 on the first die 202 that are directly below corresponding thru semiconductor vias 209 on the second die 204. By extending the redistribution layer 215 from the thru semiconductor vias 209 on the first die 202 to the junction points 219 on the first die 202, the thru semiconductor vias 209 on the first die 202 and the thru semiconductor vias 209 on the second die 204 are placed into electrical contact without requiring vertical alignment of the thru semiconductor vias 209. As such, the thru semiconductor vias 209 on the first die 202 and the thru semiconductor vias 209 on the second die 204 can be positioned at the edge of each die so as to avoid keep out zones as described in FIG. 2A.

FIG. 2C illustrates a cross sectional view around a bond pad 222 (e.g., a bond pad 222 on a first die 202 as shown in FIG. 2B) and probe 240 touchdown onto a redistribution layer 215 above a dielectric layer 242, in accordance with an embodiment of the present invention. The probe 240 is placed on the redistribution layer 215 (e.g., during a SORT process) to test the functionality of a die on which the bond pad 222 resides. The redistribution layer 215 shown in FIG. 2C is a conductive layer that allows current to flow between the probe 240 and the top metal layer 246. In one embodiment of the present invention, the portion 220 in FIG. 2C of the redistribution layer 215 that is above the dielectric layer 242 is at least large enough to allow a probe 240 to be placed on it. In one embodiment of the present invention, the probe 240 is placed only on the portion 220 of the redistribution layer 215 that is above the dielectric layer 242. In one embodiment, the dielectric layer 242 is a polyimide layer (e.g., the polyimide is a type of dielectric polymer, alternatively the redistribution layer 215 may be above any other dielectric material). In one embodiment of the present invention, the redistribution layer 215 is formed above a dielectric layer 242 that may be silicon-oxide, silicon-nitride, silicon carbide, polymer, spin on glass, and/or resins that have been cured and formed onto the semiconductor device shown in FIG. 2C. In another embodiment, the dielectric layer 242 is formed above a passivation layer 244. In one embodiment of the present invention, the passivation layer 244 is used to hermetically seal and protect as a barrier against moisture.

The probe point 224 is the location on the redistribution layer 215 where the probe 240 comes into contact with the redistribution layer 215. In one embodiment of the present invention, the probe point 224 may be located on any portion 220 of the redistribution layer 215 that is above the dielectric layer 242. The probe 240 is often repeatedly placed on to the same probe point 224 in order to perform a thorough check of the functionality of a particular die. The repeated placements of the probe 240 onto the redistribution layer 215 can result in the exposure of the dielectric layer 242 to air because the redistribution layer 215 is often a soft metal such as aluminum or 0.05% copper doped aluminum that tears away. The dielectric layer 242 does not oxidize when exposed to air and therefore does not corrode. The top metal layer 246 (e.g., the top metal layer may be copper) is never exposed to air and therefore does not corrode when the probe 240 is placed on the redistribution layer 215. As such, the bond pad 222 is not torn apart after repeated application of the probe 240. In one embodiment of the present invention, the probe 240 must be repeatedly applied to ensure that all circuitry within a particular integrated circuit is operating properly. In one embodiment of the present invention, the probe 240 is used during the SORT testing process.

FIGS. 3A-3F illustrates a method for forming a redistribution layer on a first die 202, in accordance with an embodiment of the present invention. In FIG. 3A, a semiconductor layer 300 is illustrated (e.g., a semiconductor material such as monocrystalline silicon may be used for the semiconductor layer 300). A transistor layer 301 on which there is active circuitry may be formed on the semiconductor layer 300 (e.g., between the semiconductor layer 300 and the metalization layers 302). A number of metal layers 302 (e.g., the metal layers 302 may include a top metal layer 246 as illustrated in FIG. 2C, and a number of additional metal layers separated by inter-layer dielectrics) may be formed above the semiconductor layer 300 and the transistor layer 301. A die bond pad 222 (e.g., as described in FIG. 2C) and a thru via bond pad 322 may be formed on the top metal layer (e.g., the top metal layer 246 as illustrated in FIG. 2C) within the metal layers 302. Next, a passivation layer 244 is formed above the metal layers 302 to act as a barrier against moisture. In one embodiment, the passivation layer 244 is silicon nitride. In another embodiment, the passivation layer 244 is a composite film stack which includes a lower oxide (e.g., SiO₂) and an upper silicon nitride (e.g., Si₃N₄) or a silicon oxynitride (e.g., SiOₓN_{y}). A dielectric layer 242 is formed above the passivation layer 244 to provide scratch protection to the first die 202. In one embodiment of the present invention, the dielectric layer 242 may be silicon-oxide, silicon-nitride, silicon carbide, polymer, spin on glass, and/or resins that have been cured and formed on top of the passivation layer 244. In one embodiment of the present invention, the dielectric layer 242 is a polyimide layer.

In FIG. 3B, the passivation layer 244 and the dielectric layer 242 is etched using a standard etch process to form an opening above the metal layers 302. In one embodiment of the present invention, an exposed surface of the metal layers 302 is a die bond pad 222 as described in FIG. 2C. In one embodiment of the present invention, an exposed surface of the metal layers 302 is a thru via bond pad 322 and is directly above a location where a thru semiconductor via 209 (as shown in FIG. 3D) will be formed.

Next, in FIG. 3C, a redistribution layer 215 is formed above the dielectric layer 242. In one embodiment, the redistribution layer 215 is formed through blanket deposition onto the surface above die bond pad 222 and thru via bond pad 322 by sputtering or chemical vapor deposition (CVD). The redistribution layer 215 was previously described in detail in FIGS. 2A-2C. In one embodiment of the present invention, the redistribution layer 215 is 0.05% copper doped aluminum. In one embodiment of the present invention, the redistribution layer 215 is greater than 1 micron in thickness when a 0.05% copper doped aluminum is used for the redistribution layer 215. In one embodiment of the present invention, the redistribution layer 215 includes a titanium base that is thicker than 1000 angstroms. Other embodiments of the redistribution layer 215 in FIG. 3C are the same as the redistribution layer 215 described in FIG. 2A.

Next, in FIG. 3D, the redistribution layer 215 is patterned above the dielectric layer 242. In one embodiment, the redistribution layer 215 is patterned using well known photoresist and etching techniques and is patterned above the dielectric layer 242 to form an alternate probe area (e.g., such as the portion 220 in FIG. 2C) for testing the functionality of the active circuitry within the first die 202 and patterned to electrically route a thru semiconductor via (e.g., such as a thru semiconductor via 209 that will be formed under thru via bond pad 222 as shown in FIG. 3F) within the first die 202 to an alternate junction point (e.g., junction point 219 as shown in FIG. 2B). In one embodiment of the present invention, the portion of the redistribution layer 215 which is above the dielectric layer 242 is at least large enough to allow a probe 240 to be placed on it as described in FIG. 2C. In another embodiment, the portion of the redistribution layer 215 which is above the dielectric layer 242 is at least the size of bond pad 222. In one embodiment of the present invention, the redistribution layer 215 extends electrical connection from the thru semiconductor via 209 in FIG. 3D to a junction point on a first die that is directly below a corresponding thru semiconductor via on a second die (e.g., as shown in FIG. 2B, a junction point 219 on the first die 202 that is directly below corresponding thru semiconductor via 209 on the second die 204).

Next, in FIG. 3E, an additional dielectric layer 342 is optionally formed and patterned above the redistribution layer 215 to provide scratch protection to the redistribution layer 215. In one embodiment of the invention, the dielectric layer 342 is formed after testing of the functionality of active circuitry within the first die. In another embodiment of the invention, a scrub step is performed to expose the redistribution layer 215 directly underneath the area where a probe 240 will be placed (e.g., as shown in FIG. 3E). In another embodiment, the dielectric layer 342 is patterned to allow the probe 240 to be placed directly on the redistribution layer 215 below the dielectric layer 342. In one embodiment of the present invention, the dielectric layer 342 may be silicon-oxide, silicon-nitride, silicon carbide, polymer, spin on glass, and/or resins that have been cured and formed on top of the redistribution layer 215. In one embodiment of the present invention, the dielectric layer 342 is a polyimide layer.

Next, in FIG. 3F, the semiconductor layer 300 is thinned and a thru semiconductor via 209 is formed through the semiconductor layer 300. In one embodiment, the semiconductor layer 300 may be thinned using one or more mechanical and/or chemical processes such as a polishing process for example. In one embodiment, etching through the backside of semiconductor layer 300 may form the thru semiconductor via 209. In another embodiment, the thru semiconductor via 209 may be etched only to the transistor layer 301 that is located between the semiconductor layer 300 and the metal layers 302. In one embodiment, interconnects (not shown) within the metal layers 302 may electrically connect the thru semiconductor via 209 to the thru via bond pad 322 on the top metal layer (e.g., top metal layer 246 shown in FIG. 2C). In another embodiment, the thru semiconductor via 209 may be etched from the backside of semiconductor 300 to the thru via bond pad 322 on the top metal layer (e.g., top metal layer 246 as shown in FIG. 2C) of the metal layers 302. In one embodiment of the present invention, a separate saw is used to cut each first die 202 from a wafer after the thru semiconductor vias 209 are formed.

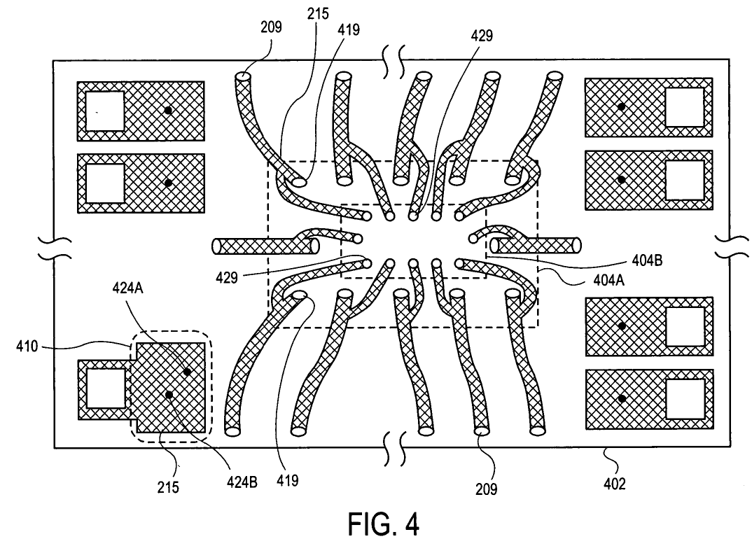

FIG. 4 illustrates a top view of an exemplary die 402 having a patterned redistribution layer 215 that allows the exemplary die 402 to be stacked with a second die that can be one of two sizes (either a die size 404A or a die size 404B), and allows a larger alternate probe area 410 for probe touchdowns on the redistribution layer 215, in accordance with an embodiment of the present invention. In one embodiment of the present invention, the exemplary die 402 shown in FIG. 4 may be used as a substitute for die 202 in FIGS. 2A-2C. In one embodiment of the present invention, the larger alternate probe area 410 is used to accommodate specific requirements for larger probes that might be required for testing, or for testing that requires extensive probe touchdowns. (e.g., a particularly thick probe 240 as shown in FIG. 2C may require a larger alternate probe area 410 above a dielectric layer 242 as shown in FIG. 2C for testing). In one embodiment of the present invention, the alternate probe area 410 may be large enough to allow multiple probe points (as shown in probe points 424A and 424B) so as to minimize the tearing away of the redistribution layer 215.

FIG. 4 illustrates that the redistribution layer 215 may be patterned to allow the die 402 to be coupled to a second die that can have a size 404A or have a size 404B. In FIG. 4, the redistribution layer 215 routes each of the thru semiconductor vias 209 on the die 402 to junction points 419 on the first die 402 and to junction points 429 on the first die 402 (e.g., two different junction point locations on exemplary die 402 to accommodate either the second die having a physical size 404A or the second die having a physical size 404B). The junction points 419 correspond to locations that are directly below corresponding thru semiconductor vias 209 on a second die having the size 404A. The junction points 429 correspond to locations that are directly below a corresponding thru semiconductor vias 209 on a second die having the size 404B. By extending the redistribution layer 215 from the thru semiconductor vias 209 on the die 402 to the junction points 419 on the die 402 and to the junction points 429 on the die 402, the thru semiconductor vias 209 on the die 402 are placed into electrical contact with a second die (e.g., the second die can either be the size 404A or the size 404B) without requiring vertical alignment of the thru semiconductor vias 209 as previously described in FIG. 2B. In one embodiment of the present invention, the redistribution layer 215 in FIG. 4 may be patterned to allow more than two sizes of die be coupled to die 402.

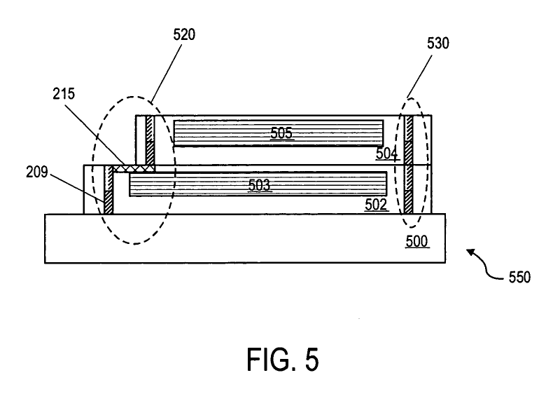

FIG. 5 illustrates a side view of a first die 502 and a second die 504, each having edge positioned thru semiconductor vias 209 that are in electrical contact with each other to form a stacked device 550 through the use of a redistribution layer 215 as shown in 520 and by vertical stacking as shown in 530, in accordance with an embodiment of the present invention. A package substrate 500 is below the first die 502 and the second die 504. In FIG. 5, the redistribution layer 215 as shown in 520 allows the thru semiconductor vias 209 in the first die 502 to be electrically connected to the thru semiconductor vias 209 in the second die 504. Also shown in 530 on FIG. 5, vertical stacking of the thru semiconductor vias 209 in the first die 502 and the thru semiconductor vias 209 in the second die 504 forms electrical connection. As such, in one embodiment of the present invention, both vertical stacking of thru semiconductor vias 209 (as shown in 530) and the use of a redistribution layer 215 (as shown in 520) may be used.

It should be noted that the embodiments disclosed herein may be applied to the formation of any microelectronic device. Certain features of the embodiments of the claimed subject matter have been illustrated as described herein, however, modifications, substitutions, changes and equivalents will be evident to those skilled in the art. Additionally, while several relationships have been described in detail, it is contemplated by those of skill in the art that several of the methods may be performed without the use of the others, or additional functions or relationships between methods may be established and still remain in accordance with the claimed subject matter. It is, therefore, to be understood that the appended claims are intended to cover all such modifications and changes as fall within the true spirit of the claimed subject matter.

1. A semiconductor device, comprising:
a top metal layer above a semiconductor substrate;
a dielectric layer above said top metal layer; and
a conductive layer above said dielectric layer patterned to form an alternate probe area within said semiconductor device and patterned to electrically route a thru semiconductor via within said semiconductor device to an alternate junction point.

2. The semiconductor device of claim 1, wherein said dielectric layer is chosen from a group comprising of silicon-oxide, silicon-nitride, silicon carbide, polymer, spin on glass, and resin.

3. The semiconductor device of claim 1, wherein said alternate junction point electrically connects said semiconductor device with a thru semiconductor via within a second semiconductor device that is stacked above said semiconductor device.

4. The semiconductor device of claim 1, wherein an additional dielectric layer is formed above said conductive layer and is chosen from a group comprising of silicon-oxide, silicon-nitride, silicon carbide, polymer, spin on glass, and resin.

5. The semiconductor device of claim 1, wherein said conductive layer is 0.05% copper doped aluminum, is greater than 1 micron in thickness, and has a titanium base that is thicker than 1000 angstroms.

6. A process, comprising:
patterning a conductive layer that extends from a bond pad to an alternate probe area above a dielectric layer on a first semiconductor device; and
placing a probe on said alternate probe area so as to test the functionality of the active circuitry within said first semiconductor device.

7. The process of claim 6, wherein said conductive layer also is patterned to electrically connect a first thru semiconductor via within said first semiconductor device to a second thru semiconductor via within a second semiconductor device.

8. The process of claim 6, wherein said conductive layer is directly above a dielectric layer chosen from a group comprising of silicon-oxide, silicon-nitride, silicon carbide, polymer, spin on glass, and resin.

9. The process of claim 6, wherein an additional dielectric layer is formed above said conductive layer and is chosen from a group comprising of silicon-oxide, silicon-nitride, silicon carbide, polymer, spin on glass, and resin.

10. The process of claim 6, wherein said conductive layer is 0.05% copper doped aluminum, is greater than 1 micron in thickness, and has a titanium base that is thicker than 1000 angstroms.

11. A stacked semiconductor device, comprising:
a first substrate having a first thru semiconductor via and a conductive layer that extends from said first thru semiconductor via to a junction point above a dielectric layer on said first substrate; and
a second substrate above said first substrate having a second thru semiconductor via that contacts said junction point to form an electrical connection between said first substrate and said second substrate.

12. The stacked semiconductor device of claim 11, wherein said dielectric layer is chosen from a group comprising of silicon-oxide, silicon-nitride, silicon carbide, polymer, spin on glass, and resin.

13. The stacked semiconductor device of claim 11, wherein said first thru semiconductor via and said second thru semiconductor via are edge positioned within said first substrate and said second substrate respectively and have no keep out zones within their active regions.

14. The stacked semiconductor device of claim 11, wherein an additional dielectric layer is formed above said conductive layer and is chosen from a group comprising of silicon-oxide, silicon-nitride, silicon carbide, polymer, spin on glass, and resin.

15. The stacked semiconductor device of claim 11, wherein said conductive layer is 0.05% copper doped aluminum, is greater than 1 micron in thickness, and has a titanium base that is thicker than 1000 angstroms.

16. The stacked semiconductor device of claim 11, wherein a probe is placed on said conductive layer so as to test the functionality of the active circuitry within said stacked semiconductor device.

17. A method, comprising:
forming a conductive layer that is above a dielectric layer and a top metal layer on a first device and which extends a first thru semiconductor via within said first device to a junction point above said dielectric layer; and
stacking said first device to a second device by electrically contacting said junction point to a second thru semiconductor via within said second device to form an electrical connection between said first device and said second device.

18. The method of claim 17, wherein said dielectric layer is chosen from a group comprising of silicon-oxide, silicon-nitride, silicon carbide, polymer, spin on glass, and resin.

19. The method of claim 17, wherein said first device and said second device have no keep out zones within their active regions.

20. The method of claim 17, wherein an additional dielectric layer is formed above said conductive layer.

21. The method of claim 20, wherein said additional dielectric layer is chosen from a group comprising of silicon-oxide, silicon-nitride, silicon carbide, polymer, spin on glass, and resin.

22. The method of claim 17, wherein said conductive layer is 0.05% copper doped aluminum.

23. The method of claim 22, wherein said conductive layer is greater than 1 micron in thickness and has a titanium base that is thicker than 1000 angstroms.

24. The method of claim 17, wherein said conductive layer also extends from a bond pad to an alternate probe area above said dielectric layer to test the functionality of the active circuitry within said first device.

25. A system, comprising:
means for patterning a conductive layer that extends from a bond pad to an alternate probe area above a dielectric layer on a first semiconductor device; and
means for placing a probe on said alternate probe area so as to test the functionality of the active circuitry within said first semiconductor device.

26. The system of claim 25, wherein said conductive layer also is patterned to electrically connect a first thru semiconductor via within said first semiconductor device to a second thru semiconductor via within a second semiconductor device.

27. The system of claim 25, wherein said conductive layer is 0.05% copper doped aluminum, is greater than 1 micron in thickness, and has a titanium base that is thicker than 1000 angstroms.
